(19) United States
(12) Patent Application Publication
(10) Pub. No.: US 2026/0044073 A1
(43) Pub. Date: Feb. 12, 2026

(54) NEGATIVE RESIST PATTERN FORMING PROCESS

(71) Applicant: Shin-Etsu Chemical Co., Ltd., Tokyo (JP)

(72) Inventors: Satoshi Kusama, Joetsu-shi (JP); Shun Kikuchi, Joetsu-shi (JP); Masaki Ohashi, Joetsu-shi (JP)

(73) Assignee: Shin-Etsu Chemical Co., Ltd., Tokyo (JP)

(21) Appl. No.: 19/068,384

(22) Filed: Mar. 3, 2025

(30) Foreign Application Priority Data
Mar. 8, 2024 (JP) 2024-035809

(51) Int. Cl. G03F 7/004; G03F 7/00; G03F 7/038; G03F 7/32

(52) U.S. Cl. CPC G03F 7/0045; G03F 7/0382; G03F 7/0388; G03F 7/322; G03F 7/70033

(57) ABSTRACT

A negative resist pattern forming process, comprising: (i) forming a resist film on a substrate using a resist composition containing a hypervalent iodine compound, a carboxylic acid compound, and a solvent; (ii) exposing the resist film with a high-energy radiation; and (iii) developing the exposed resist film using a developer that dissolves an unexposed portion and does not dissolve an exposed portion.

### CROSS-REFERENCE TO RELATED APPLICATIONS

This non-provisional application claims priority under 35 U.S.C. § 119(a) on Patent Application No. 2024-035809 filed in Japan on Mar. 8, 2024, the entire contents of which are hereby incorporated by reference.

### TECHNICAL FIELD

The present invention relates to a negative resist pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, devices of 10-nm node are manufactured in a mass scale by the double, triple or quadro-patterning version of the immersion ArF lithography. Active research efforts have been made on the manufacture of 7-nm node devices by the next generation extreme ultraviolet (EUV) lithography of wavelength 13.5 nm.

As the feature size is reduced, image blurs due to acid diffusion become a problem (see Non-Patent Document 1). To ensure resolution for small size patterns with a feature size of 45 nm et seq., not only an improvement in dissolution contrast is requisite, but the control of acid diffusion is also important (see Non-Patent Document 2). However, since the chemically amplified resist composition increases the sensitivity and contrast by the diffusion of the acid, when the acid diffusion is suppressed to the utmost limit by lowering the post exposure bake (PEB) temperature or shortening the PEB time, the sensitivity and contrast are remarkably lowered.

It is effective to suppress acid diffusion by adding an acid generator that generates a bulky acid. Therefore, it has been proposed to copolymerize an acid generator of an onium salt having a polymerizable olefin in a polymer. However, in pattern formation of a resist film having a feature size of 16 nm or more, it is considered that a pattern cannot be formed with a chemically amplified resist composition from the viewpoint of acid diffusion, and development of a non-chemically amplified resist composition is desired.

Examples of the material for the non-chemically amplified resist composition include polymethyl methacrylate (PMMA). PMMA is a positive resist material in which the main chain is cut by EUV irradiation and the molecular weight is reduced, so that the solubility of the organic solvent in the developer is improved.

Hydrogensilsesquioxane (HSQ) is a negative resist material that becomes insoluble in an alkaline developer by crosslinking due to a condensation reaction of silanol generated by EUV irradiation. Chlorine-substituted calixarenes also function as negative resist materials. Since these negative resist materials have a small molecular size before crosslinking and no blurring due to acid diffusion, the negative resist materials have lower edge roughness and very high resolution, and are used as pattern transfer materials for showing the resolution limit of an exposure apparatus. However, these materials have insufficient sensitivity and require further improvement.

A factor that makes development of materials for EUV lithography difficult is a small number of photons in EUV exposure. The energy of EUV is much higher compared to ArF excimer laser, and the photon number of EUV exposure is 1/14 of that of ArF exposure. Furthermore, the dimension of the pattern formed by the EUV exposure is less than or equal to half of that of the ArF exposure. For this reason, the EUV exposure is easily affected by the variation in the number of photons. The variation in the number of photons in the radiation light region having a very short wavelength is shot noise of a physical phenomenon, and this influence cannot be eliminated. Therefore, so-called Stochastics has attracted attention. Although the influence of shot noise cannot be eliminated, how to reduce this influence has been discussed. A phenomenon has been observed in which not only critical dimension uniformity (CDU) and line width roughness (LWR) increase due to the influence of shot noise, but also holes are blocked with a probability of several millions. When the hole is blocked, a current failure occurs and the transistor does not operate, which adversely affects the performance of the entire device. In consideration of practical sensitivity, a resist composition containing PMMA or HSQ as a principal component is greatly affected by Stochastics, and desired resolution performance cannot be obtained.

As a method of reducing the influence of shot noise on the resist side, introduction of an element having large absorption of EUV light has attracted attention. Patent Document 1 proposes a chemically amplified resist composition containing an iodine atom that absorbs a large amount of EUV light. However, as described above, with the chemically amplified resist composition, excellent resolution performance cannot be realized in EUV lithography in which the size is increasingly miniaturized in the future.

Patent Document 2 proposes a negative resist composition using a tin compound. Since the tin element having a large absorption of EUV light is contained as a principal component, Stochastics is improved, and high sensitivity and high resolution can be realized. However, such a so-called metal resist has many problems such as insufficient solubility in a resist solvent, storage stability, and defects due to residues after etching.

On the other hand, Patent Document 3 proposes a positive resist composition using a hypervalent iodine compound. Since this contains an iodine element having high absorption of EUV light, Stochastics is improved similarly to the metal resist, and high sensitivity and high resolution can be realized. Furthermore, since it is composed of only organic molecules, it is possible to improve developer solubility and reduce defects due to residues which are problems of the metal resist. However, as a resist composition to be used for photolithography, there are a positive type in which an exposed portion is dissolved to form a pattern and a negative type in which a pattern is formed while leaving the exposed portion. The type can be selected based on ease of use according to the form of a required resist pattern. However, since this resist composition is the positive type, there is a problem that it cannot be applied when the required pattern is a negative type.

### CITATION LIST

Patent Document 1: JP-A 2018-005224
Patent Document 2: JP-A 2021-503482
Patent Document 3: JP-A 2023-167368
Patent Document 4: JP-A 2015-180928
Patent Document 5: JP-A 2018-095853
Non-Patent Document 1: SPIE Vol. 5039 p1 (2003)
Non-Patent Document 2: SPIE Vol. 6520 p65203L-1 (2007)

### SUMMARY OF THE INVENTION

The present invention has been made in view of the above circumstances, and an object thereof is to provide a negative resist pattern forming process using a non-chemically amplified resist composition excellent in sensitivity and resolution in photolithography using a high-energy radiation, particularly electron beam (EB) lithography and EUV lithography.

As a result of intensive studies to achieve the above object, the present inventors have found that by combining a resist composition containing, as principal components, a hypervalent iodine compound having at least two acyloxy groups and a carboxylic acid compound with an appropriate developer, a negative resist pattern having extremely high sensitivity and excellent in resolution is obtained, which is thus quite useful in precise micropatterning, and thus the present invention has been achieved.

That is, the present invention provides the following negative resist pattern forming process.

1. A negative resist pattern forming process, comprising:
(i) forming a resist film on a substrate using a resist composition containing a hypervalent iodine compound, a carboxylic acid compound, and a solvent;
(ii) exposing the resist film with a high-energy radiation; and
(iii) developing the exposed resist film using a developer that dissolves an unexposed portion and does not dissolve an exposed portion.

2. The negative resist pattern forming process according to 1, wherein the developer is an alkaline developer.

3. The negative resist pattern forming process according to 1 or 2, wherein the high-energy radiation is EB or EUV.

4. The negative resist pattern forming process according to any one of 1 to 3, wherein the hypervalent iodine compound has the following formula (1):

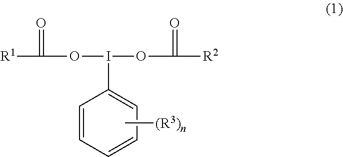

wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and intervenient atoms,
R³ is halogen or a C₁-C₄₀ hydrocarbyl group which may contain a heteroatom, and when n is an integer of 2 to 5, a plurality of R³ may be the same or different.

5. The negative resist pattern forming process according to any one of 1 to 4, wherein the carboxylic acid compound has the following formula (2):

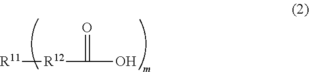

wherein m is an integer of 1 to 4,
R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, Some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety,
R¹² is a single bond or C₁-C₁₀ hydrocarbylene group, and some or all of the hydrogen atoms in the hydrocarbylene group may be substituted by a heteroatom-containing moiety, and some constituent —CH₂— in the hydrocarbylene group may be substituted by a heteroatom-containing moiety, and when m is an integer of 2 to 4, a plurality of R¹² may be the same or different.

6. The negative resist pattern forming process according to 5, wherein m is an integer of 2 to 4.

7. The negative resist pattern forming process according to any one of 1 to 6, wherein the resist composition further contains a crosslinking agent.

8. The negative resist pattern forming process according to any one of 1 to 7, wherein the resist composition further contains a radical scavenger.

### Advantageous Effects of the Invention

The negative resist pattern forming process of the present invention exhibits both high sensitivity and high resolution when processed by EB and EUV lithography and is quite useful in micropatterning.

### DETAILED DESCRIPTION OF THE INVENTION

### [Resist Composition]

The resist composition used in the negative resist pattern forming process of the present invention contains a hypervalent iodine compound having at least two acyloxy groups, a carboxylic acid compound, and a solvent.

### [Hypervalent Iodine Compound]

The hypervalent iodine compound is a generic term for iodine compounds having a valence electron formally exceeding the octet rule. The hypervalent iodine compound used in the present invention is not particularly limited as long as it has at least two acyloxy groups. Exemplary are three-coordinate iodine compounds having an oxidation number of +3 and five-coordinate iodine compounds having an oxidation number of +5.

The preferred hypervalent iodine compound is a three-coordinate hypervalent iodine compound having the following formula (1).

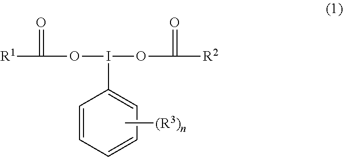

In formula (1), n is an integer of 0 to 5.

In formula (1), R¹ and R² are each independently halogen or a C₁-C₁₀ hydrocarbyl group which may contain a heteroatom. R¹ and R² may bond together to form a ring with the carbon atoms to which they are attached and intervenient atoms, Specific examples of the halogen atom include fluorine, chlorine, bromine, and iodine. The C₁-C₁₀ hydrocarbyl group may be saturated or unsaturated and straight, branched or cyclic. Specific examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₂-C₁₀ alkenyl groups such as vinyl and allyl; C₆-C₁₀ aryl groups such as phenyl and naphthyl; and combinations thereof. Also some or all of the hydrogen atoms of the hydrocarbyl groups may be substituted by a heteroatom-containing moiety such as oxygen, sulfur, nitrogen or halogen, and some constituent —CH₂— may be substituted by a heteroatom-containing moiety such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or a carboxylic anhydride (—C(═O)—O—C(═O)—), or the like. R¹ and R² are preferably C₁-C₄ hydrocarbyl groups.

In formula (1), R³ is halogen or a C₁-C₄₀ hydrocarbyl group which may contain a heteroatom. When n is an integer of 2 to 5, a plurality of R³ may be the same or different. Specific examples of the halogen atom include fluorine, chlorine, bromine, and iodine. The C₁-C₄₀ hydrocarbyl group may be saturated or unsaturated and straight, branched or cyclic. Specific examples thereof include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl and adamantylmethyl; and C₆-C₄₀ aryl groups such as phenyl, naphthyl, and anthracenyl. Also some or all of the hydrogen atoms of the hydrocarbyl groups may be substituted by a heteroatom-containing moiety such as oxygen, sulfur, nitrogen or halogen, and some constituent —CH₂— may be substituted by a heteroatom-containing moiety such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or a carboxylic anhydride (—C(═O)—O—C(═O)—), or the like.

Specific examples of the hypervalent iodine compound having formula (1) are shown below, but not limited thereto.

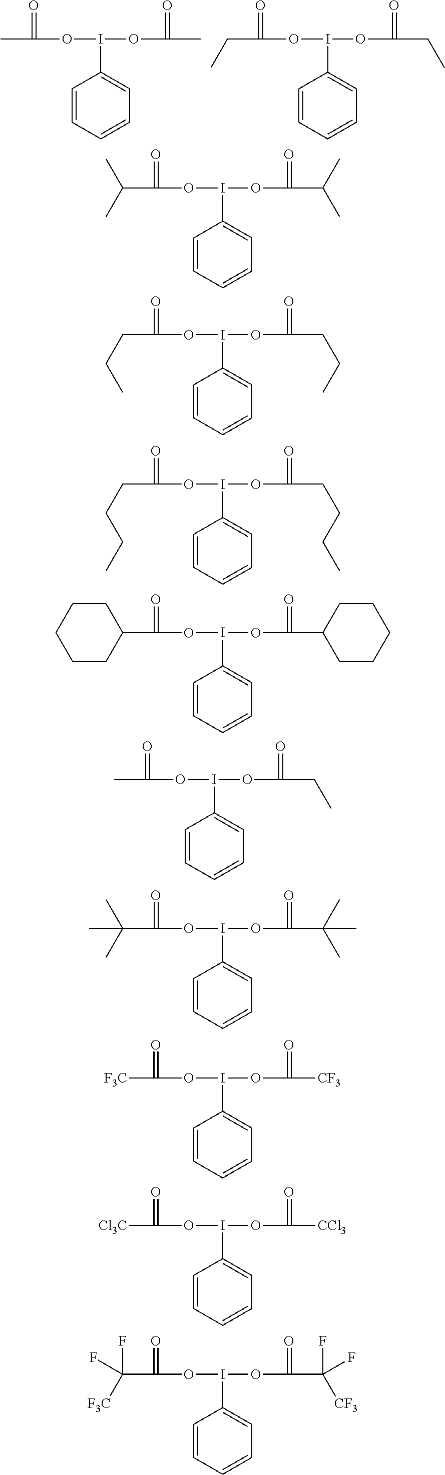

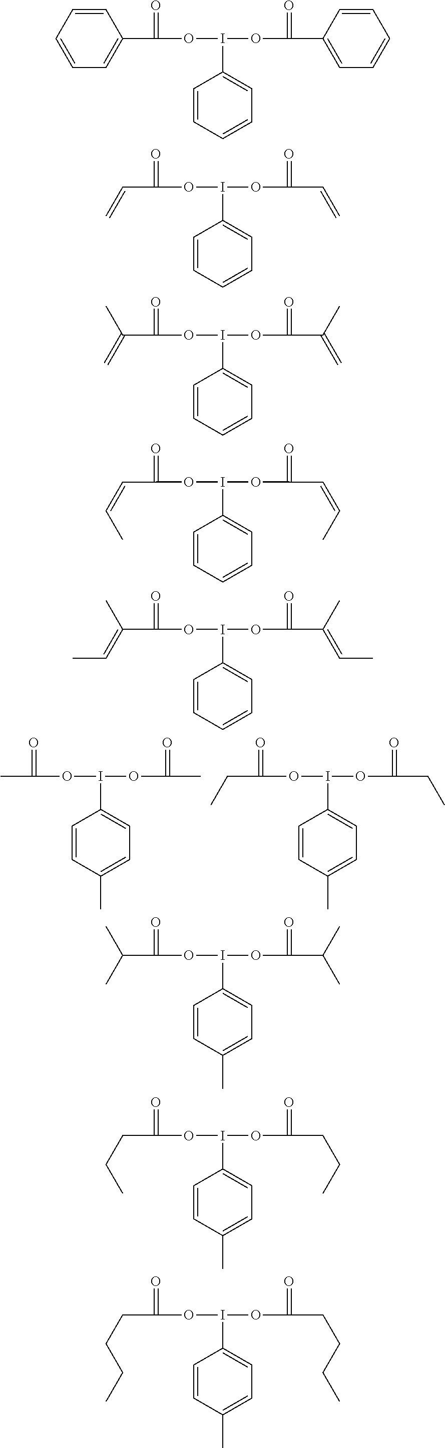

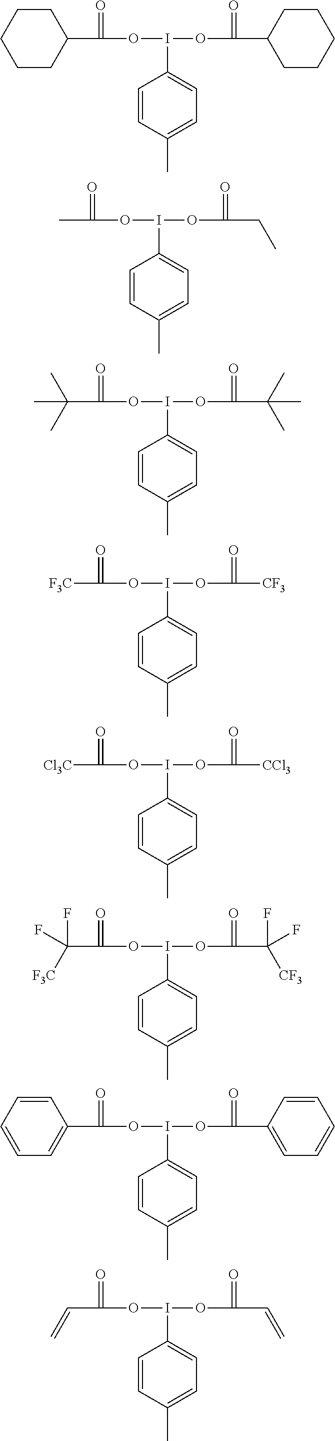

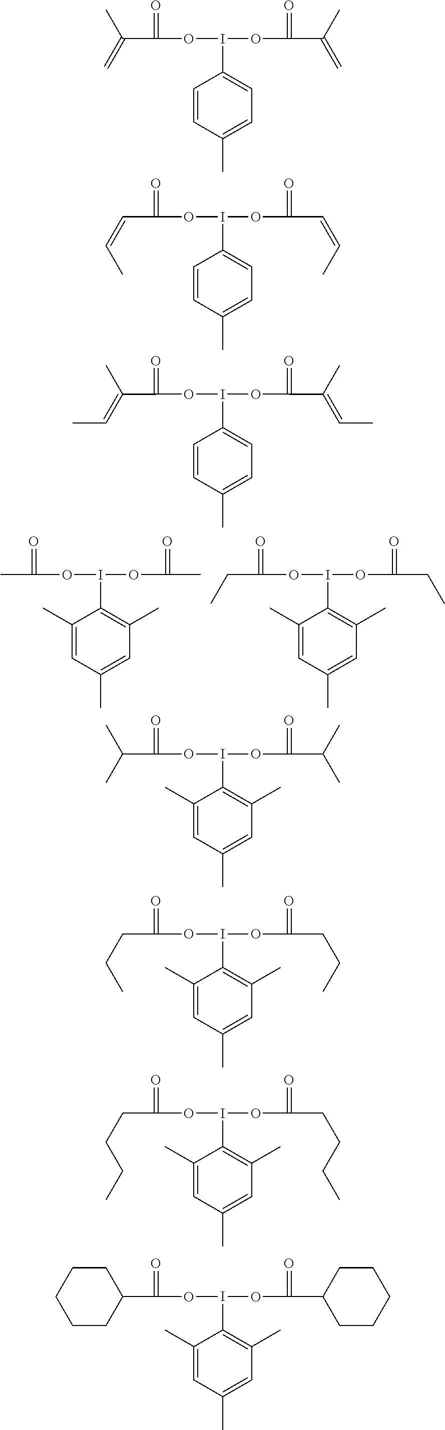

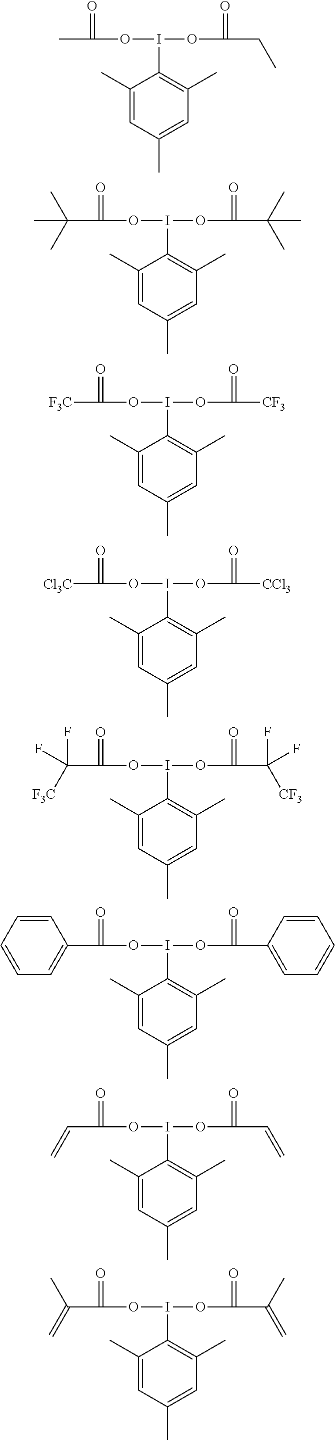

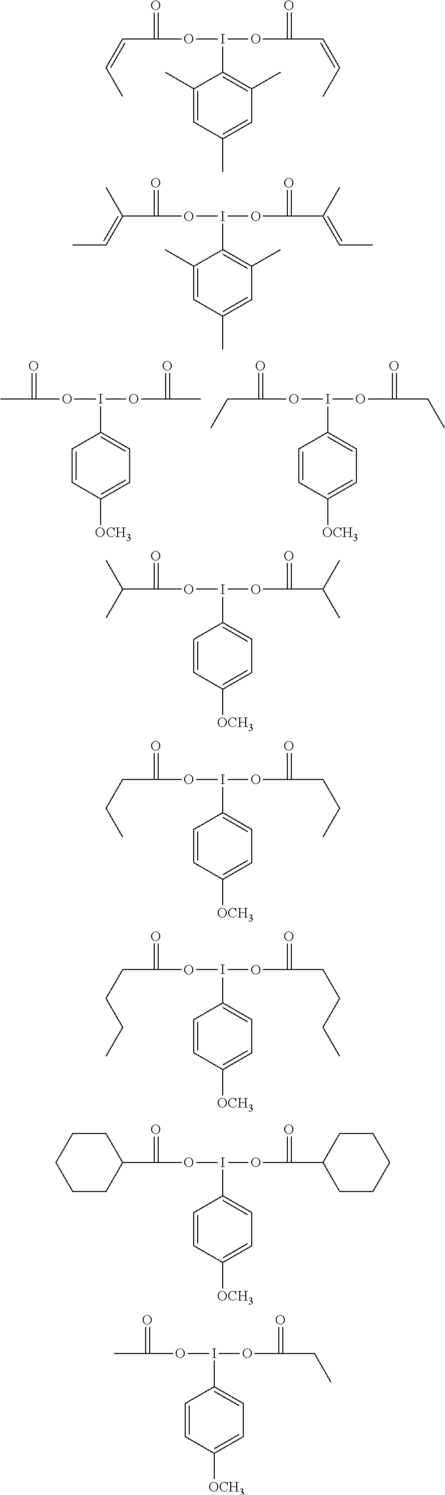

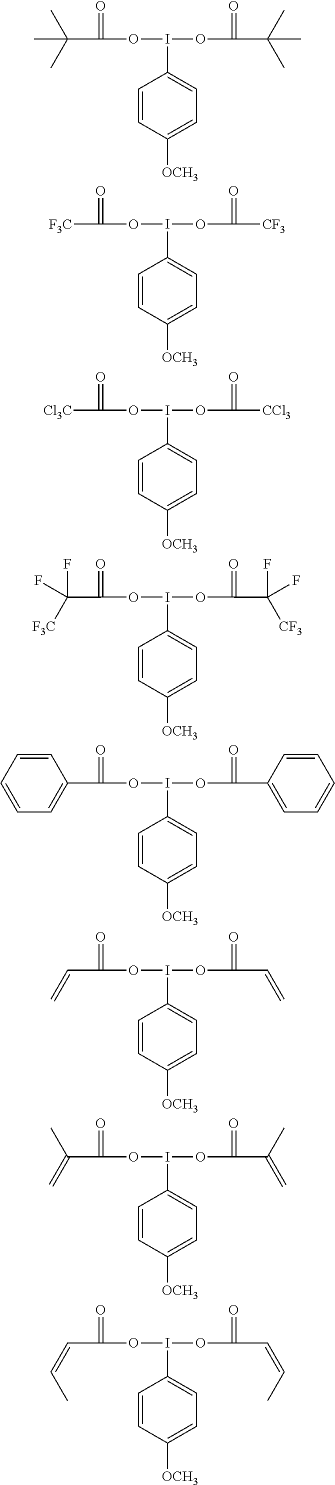

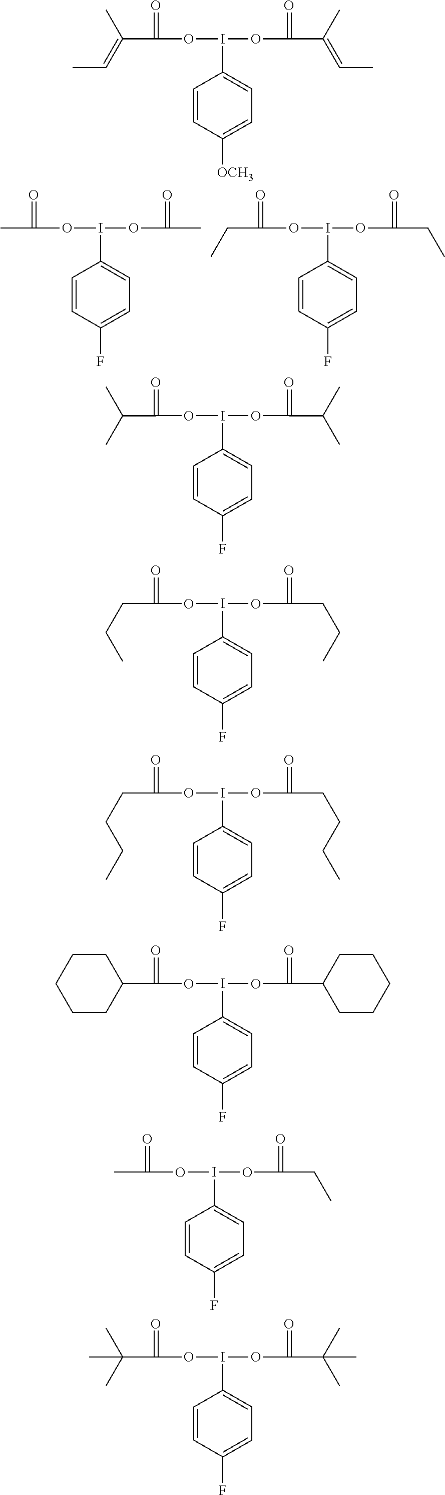

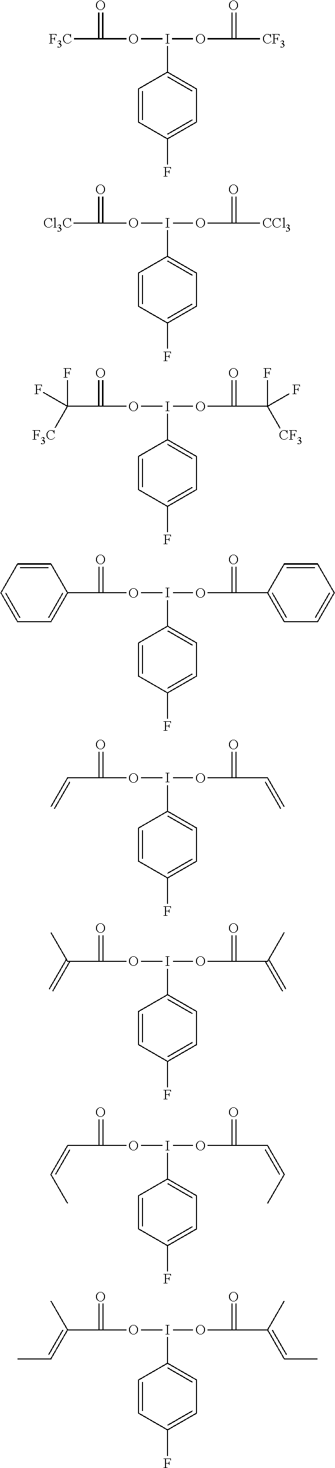

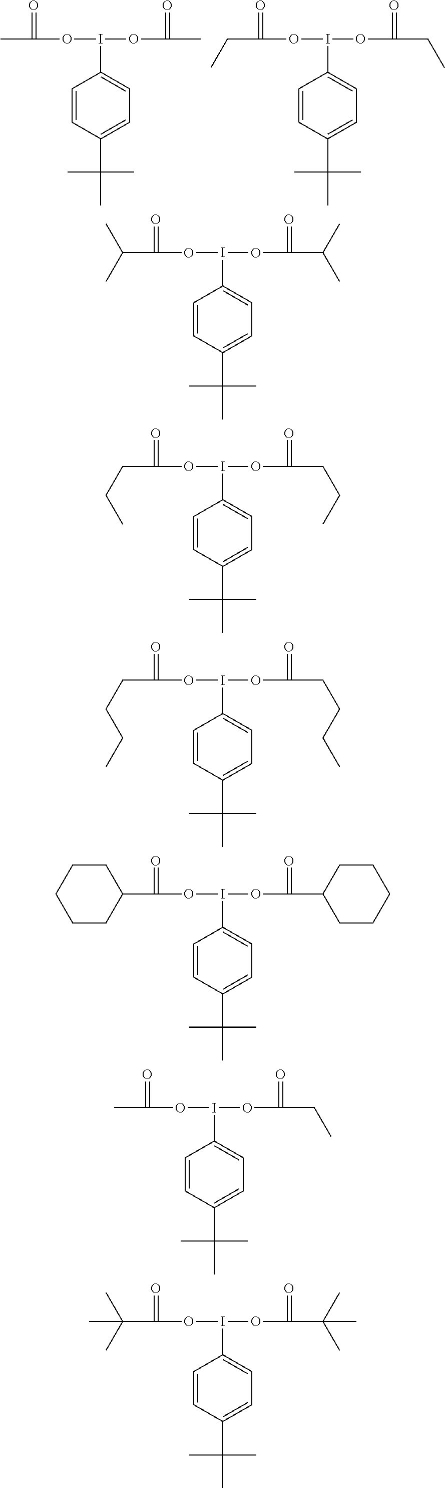

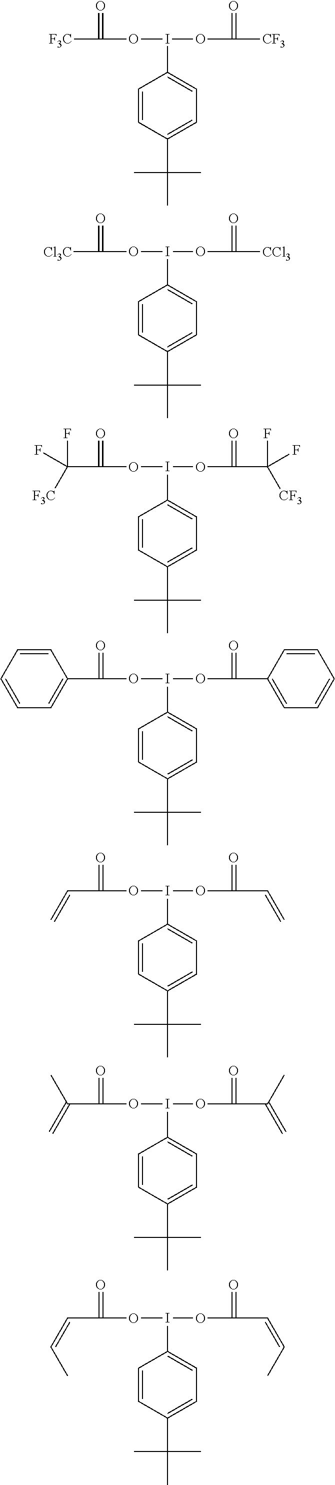

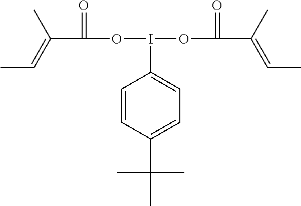 [SMILES: C/C=C(\C)C(=O)OI(OC(=O)/C(C)=C/C)c1ccc(C(C)(C)C)cc1]

### [Carboxylic Acid Compound]

As the carboxylic acid compound used herein, all compounds which are generally defined as carboxylic acid compound in the organic chemistry field are applicable. A carboxylic acid having the following formula (2) is preferred.

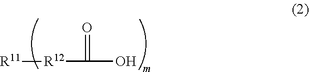

In formula (2), m is an integer of 1 to 4. R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, Some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety, R¹² is a single bond or C₁-C₁₀ hydrocarbylene group, and some or all of the hydrogen atoms in the hydrocarbylene group may be substituted by a heteroatom-containing moiety, and some constituent —CH₂— in the hydrocarbylene group may be substituted by a heteroatom-containing moiety, and when m is an integer of 2 to 4, a plurality of R¹² may be the same or different.

The m-valent hydrocarbon group represented by R¹¹ may be saturated or unsaturated and straight, branched or cyclic. The m-valent hydrocarbon group is a group obtained by removing m number of hydrogen atoms from a hydrocarbon. Specific examples of the hydrocarbon include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Specific examples of C₁-C₄₀ alkanes include methane, ethane, propane, butane, pentane, hexane, heptane, octane, nonane, decane, and structural isomers thereof.

Specific examples of C₂-C₄₀ alkenes include ethylene, propylene, butene, pentene, hexene, heptene, octene, nonene, decene, and structural isomers thereof.

Specific examples of C₂-C₄₀ alkynes include acetylene, propyne, butyne, pentyne, hexyne, heptyne, octyne, nonyne, decyne, and structural isomers thereof.

Specific examples of C₃-C₄₀ cyclic saturated hydrocarbons include cyclopropane, cyclobutane, cyclohexane, cycloheptane, cyclooctane, adamantane, and norbornane.

Specific examples of C₃-C₄₀ cyclic unsaturated hydrocarbons include cyclopropene, cyclobutene, cyclopentene, cyclohexene, cycloheptene, cyclooctene, and norbornene.

Specific examples of C₆-C₄₀ aromatic hydrocarbons include benzene, naphthalene, and biphenyl.

The m-valent heterocyclic group represented by R¹¹ is obtained by removing m number of hydrogen atoms from a heterocyclic compound. Specific examples of the heterocyclic compound include furane, pyridine, pyrazole, and thiazolidine.

In the m-valent hydrocarbon group and m-valent heterocyclic group, some or all of the hydrogen atoms may be substituted by a heteroatom-containing moiety such as oxygen, sulfur, nitrogen or halogen, so that the group may contain hydroxy, cyano, fluorine, chlorine, bromine, or iodine. In the m-valent hydrocarbon group, some constituent —CH₂— may be substituted by a heteroatom-containing moiety such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

The hydrocarbylene group represented by R¹² may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl, C₃-C₂₀ cyclic saturated hydrocarbylene groups such as cyclopentanediyl, cyclohexanediyl, norbornanediyl, and adamantanediyl, C₂-C₂₀ unsaturated aliphatic hydrocarbylene groups such as vinylene and propene-1,3-diyl, C₆-C₂₀ arylene groups such as phenylene and naphthylene, and combinations thereof. In the hydrocarbylene group, some or all of the hydrogen atoms may be substituted by a heteroatom-containing moiety such as oxygen, sulfur, nitrogen or halogen, and some constituent —CH₂— may be substituted by a heteroatom-containing moiety such as oxygen, sulfur or nitrogen, so that the group may contain hydroxy, cyano, fluorine, chlorine, bromine, iodine, carbonyl, ether bond, thioether bond, ester bond, sulfonic ester bond, carbonate bond, carbamate bond, lactone ring, sultone ring, or carboxylic anhydride.

Of the carboxylic acid compounds, those compounds of formula (2) wherein m is an integer of 2 to 4 are preferred. In this case, when being mixed with the hypervalent iodine compound, they form a robust resist film with high molecular weight, which is preferable in terms of etching resistance and developer resistance.

Specific examples of the carboxylic acid compound include, but are not limited to, those shown below.

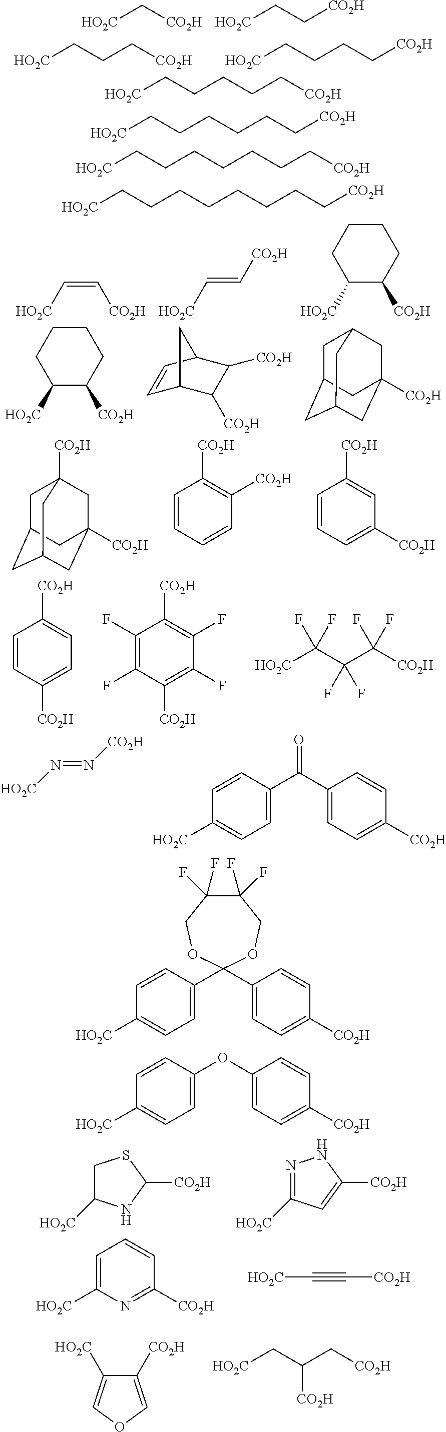

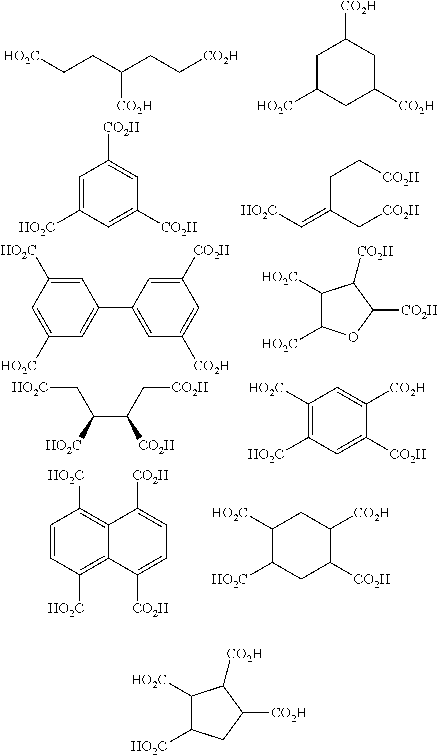

In the resist composition, the hypervalent iodine compound and the carboxylic acid compound are preferably present in a content ratio such that the molar ratio of the hypervalent iodine compound to the carboxylic acid compound is 10:90 to 90:10, more preferably 20:80 to 80:20, and still more preferably 30:70 to 70:30. The hypervalent iodine compounds may be used alone or in combination of two or more. The carboxylic acid compounds may be used alone or in combination of two or more.

### [Solvent]

The resist composition contains a solvent. The solvent is not particularly limited as long as the hypervalent iodine compound, the carboxylic acid compound, and other components described below are dissolvable therein and a film can be formed from the resulting solution. As such a solvent, an organic solvent is preferable, and specific examples thereof include ketones such as cyclohexanone, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids such as formic acid, acetic acid, and propionic acid; lactones such as γ-butyrolactone; and mixtures thereof.

In the resist composition, the solvent is preferably present in such amounts that the resist composition may have a solids concentration of 0.1 to 20 wt %, more preferably 0.1 to 15 wt %, even more preferably 0.1 to 10 wt %. As used herein, the term solids is a general term for all components in the resist composition excluding the solvent. These solvents may be used alone or in admixture of two or more.

### [Other Components]

The resist composition may further contain a surfactant. The surfactant is preferably a fluorine-based surfactant and/or silicone-based surfactant. Specific examples of such surfactants include those described in paragraph [0276] of U.S. Patent Application Publication No. 2008/0248425. Also useful are surfactants other than the fluorine-based and/or silicon-based surfactants, as described, for example, in US 2008/0248425, paragraph [0280].

When used, the surfactant is preferably present in an amount of 0.0001 to 2 wt % based on the overall solids. The surfactants may be used alone or in combination of two or more.

The resist composition may further contain a radical scavenger. When added, the radical scavenger is effective for controlling photo-reaction and adjusting sensitivity during photolithography.

Specific examples of the radical scavenger include hindered phenols, quinones, hindered amines, and thiol compounds. Specific examples of the hindered phenol include dibutylhydroxytoluene (BHT) and 2,2′-methylenebis (4-methyl-6-tert-butylphenol). Specific examples of the quinones include 4-methoxyphenol (methoquinone) and hydroquinone. Specific examples of the hindered amines include 2,2,6,6-tetramethylpiperidine and 2,2,6,6-tetramethylpiperidine-N-oxy radical. Specific examples of the thiols include dodecanethiol and hexadecanethiol.

When used, the radical scavenger is preferably present in an amount of 0.01 to 10 wt % based on the overall solids. The radical scavenger may be used alone or in combination of two or more.

The resist composition may further contain a crosslinking agent. When added, the crosslinking agent is effective for promoting photo-reaction and increasing sensitivity of the resist during photolithography.

Specific examples of the crosslinking agent include compounds having a carbon-carbon unsaturated bond as a functional group, such as a vinyl group, a (meth) acrylate group, an allyl group, an alkynyl group, and an aromatic ring. Specific examples of the compound having a vinyl group include chain alkenes, branched alkenes, and cyclic alkenes which may have a substituent. Specific examples of the compound having a (meth) acrylate group include acrylic acid, methacrylic acid, acrylic acid ester, and methacrylic acid ester which may have a substituent. Specific examples of the compound having an allyl group include allyl alcohol, allyl ether, allyl ester, allylamide, allylamine, and allyl group-containing isocyanurates which may have a substituent. Specific examples of the compound having an alkynyl group include chain alkynes, branched alkynes, cyclic alkynes, alkynyl alcohols, alkynyl ethers, alkynyl esters, alkynylamides, alkynylamines, and alkynyl group-containing isocyanurates which may have a substituent. Specific examples of the compound having an aromatic ring include arenes, heteroarenes, styrene, stilbene, phenylacetylene, acenaphthylene, and chalcone which may have a substituent. The crosslinking agent may have only any one of the functional groups or may have a plurality of the functional groups. The number of the functional groups contained in the crosslinking agent is preferably 1 or more and 10 or less, and more preferably 2 or more and 8 or less.

When used, the crosslinking agent is preferably present in an amount of 0.01 to 50 wt % based on the overall solids. The crosslinking agents may be used alone or in combination of two or more.

The resist composition contains a hypervalent iodine compound and a carboxylic acid compound as principal components, but does not contain an acid labile group-containing base polymer or a photoacid generator as contained in a conventional chemically amplified resist composition. However, in the resist composition, the exposed portion becomes insoluble in the developer particularly by EB or EUV exposure, and a negative pattern can be formed. The mechanism is not completely clear, but is presumed as follows, for example.

The hypervalent iodine compound is a compound having at least two acyloxy groups. It is considered that when such a hypervalent iodine compound is mixed with a carboxylic acid compound, exchange of carboxylate ligands takes place as equilibration reaction. At this time, if the original carboxylate ligands are removed by any suitable means, a hypervalent iodine compound having new ligands is created. For example, if iodobenzene diacetate which is relatively readily available as the hypervalent iodine compound is mixed with a carboxylic acid compound having a high molecular weight, and the resulting low-boiling acetic acid is removed, then ligand exchange is completed. When the ligand has a sufficiently high molecular weight, a robust resist film can be formed. In particular, when a compound having a plurality of carboxy groups (for example, dicarboxylic acid compounds) is used as the carboxylic acid compound, it is considered that a high molecular weight compound of polyester structure having the hypervalent iodine compound is formed, and film formability can be secured.

The combined form of hypervalent iodine compound and carboxylic acid compound is formed during film preparation. That is, by removing the generated low-molecular carboxylic acid component during film formation and a subsequent bake step, the ligand exchange reaction is completed and a resist film is formed.

The resist film obtained from the resist composition has high solubility in a specific solvent such as an aqueous alkaline solution because hypervalent iodine causes a ligand exchange reaction. However, when this is decomposed with light, it is converted into a chemical species having low solubility in those solvents. As a result, it is presumed that the exposed portion becomes insoluble in the developer and functions as a negative resist composition.

From the foregoing presumption, it can be said that the resist composition is a non-chemically amplified resist composition. Using the resist composition, a small size pattern can be resolved without image blur due to acid diffusion as found in conventional chemically amplified resist compositions (i.e., compositions comprising a base polymer and a photoacid generator).

The resist composition is very effective, especially in the EUV lithography. This is because an iodine atom having a high absorptivity to EUV radiation is included. That is, shot noise is reduced, and higher resolution and lower LWR can be achieved.

As the EUV resist composition capable of forming a small size pattern, a metal resist containing, as a principal component, a metal tin compound having high absorptivity to EUV radiation like iodine atom has been reported (for example, Patent Document 2). However, as described above, such a metal resist has many problems such as insufficient solubility in a solvent, storage stability, and defects in the form of post etching residues due to the containment of metal elements. In contrast, since the resist composition does not use metal elements, it is advantageous over metal resists in terms of defect levels, and the problem of solvent solubility is eliminated.

Patent Documents 4 and 5 describe a resist composition containing a hypervalent iodine compound as an additive and a resist composition in which a hypervalent iodine compound is incorporated into a polymer skeleton of a base polymer. However, these patent documents only describe that the line edge roughness can be improved as the characteristics of the resist composition, and do not mention at all the possibility that the hypervalent iodine compound is photodecomposed or functions as a material of the non-chemically amplified resist composition. Furthermore, according to the description regarding the compounding amount and specific examples, the hypervalent iodine compound is not the principal component. In addition, Patent Document 3 proposes a positive resist composition using a hypervalent iodine compound, but does not mention the possibility of functioning as a negative resist by combining the resist composition with an appropriate developer. It is then believed that a negative resist pattern forming process capable of reducing shot noise during the EUV lithography and forming a small size pattern as a non-chemically amplified resist is not conceivable from these patent documents. That is, it can be said that the present invention provides a definitely novel negative resist pattern forming process.

### [Negative Resist Pattern Forming Process]

A negative resist pattern forming process of the present invention comprises (i) forming a resist film on a substrate using a resist composition, (ii) exposing the resist film with a high-energy radiation, and (iii) developing the exposed resist film using a developer that dissolves an unexposed portion and does not dissolve an exposed portion.

[Step (i)]

The step (i) is a step of forming a resist film on a substrate using the above-described resist composition. Specifically, the resist composition is applied onto a substrate for manufacturing an integrated circuit (e.g., Si, SiO₂, SiN, SiON, TiN, WSi, BPSG, SOG, organic antireflection film, and the like) or a substrate for manufacturing a mask circuit (e.g., Cr, CrO, CrON, MoSi₂, SiO₂) by an appropriate application method such as spin coating, roll coating, flow coating, dip coating, spray coating, or doctor coating so as to have a coating film thickness of 0.01 to 2 μm. The coating is prebaked on a hot plate at a temperature of preferably 60 to 200° C. for 10 seconds to 30 minutes, more preferably at 80 to 180° C. for 30 seconds to 20 minutes to form a resist film.

[Step (ii)]

The step (ii) is a step of exposing the resist film to a high-energy radiation. Specific examples of the high-energy radiation include UV, FUV, EB, EUV, X-ray, soft X-ray, excimer laser radiation, T-ray, and synchrotron radiation. On use of UV, FUV, EUV, X-ray, soft X-ray, excimer laser radiation, T-ray, and synchrotron radiation as the high-energy radiation, the resist film is exposed thereto directly or through a mask having the desired pattern so as to reach an exposure dose of preferably about 1 to 300 mJ/cm², more preferably about 10 to 200 mJ/cm². On use of EB as the high-energy radiation, writing is performed directly or using a mask for forming a target pattern with an exposure dose of preferably about 0.1 to 2000 μC/cm², more preferably about 0.5 to 1500 μC/cm². The resist composition is particularly suitable for micropatterning using EB or EUV among the high-energy radiation.

After the exposure, PEB is performed as necessary. Preferably PEB is performed on a hot plate or in an oven at 30 to 120° C. for 10 seconds to 30 minutes, more preferably at 60 to 100° C. for 30 seconds to 20 minutes.

[Step (iii)]

Step (iii) is a step of developing the exposed resist film after exposure or after PEB using a developer that dissolves an unexposed portion and does not dissolve an exposed portion. In the present invention, a negative resist pattern can be obtained by development. The developer used at this time is not particularly limited as long as it dissolves the unexposed portion and does not dissolve the exposed portion. As such a solvent, an alkaline developer is preferable, and specific examples thereof include aqueous solutions of quaternary ammonium salts, ammonia, primary amines, secondary amines, tertiary amines, inorganic alkalis, and the like. As the alkaline developer, an aqueous solution of a quaternary ammonium salt represented by tetramethylammonium hydroxide is preferable, and one having an alkaline concentration of 0.1 to 20 wt % is particularly preferable. An appropriate amount of a surfactant or an alcohol may be added to the developer. These developers may be used alone or in admixture of two or more.

After the development, rinsing is performed as necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Examples and Comparative Examples of the invention are given below by way of illustration and not by way of limitation.

### [1] Preparation of Resist Composition

### Examples 1-1 to 1-19, Comparative Examples 1-1 to 1-3

Resist compositions (R-01 to R-19) were prepared by dissolving a hypervalent iodine compound, carboxylic acid compound, a radical scavenger, and a crosslinking agent in a solvent in accordance with the recipe shown in the following Table 1, and by filtering the obtained solution through a Teflon® filter having a pore size of 0.2 μm. In addition, comparative resist compositions (CR-01 to CR-03) were prepared by mixing a base polymer, a photoacid generator, a sensitivity modifier, solvent, and 0.01 wt % of a surfactant (PF-636, manufactured by OMNOVA Solutions Inc.) in accordance with the recipe shown in the following Table 2, and filtering the obtained solution through a Teflon® filter having a pore size of 0.2 μm.

TABLE 1

| | | | Hypervalent | Carboxylic | | | | |
|---|---|---|---|---|---|---|---|---|
| | | | iodine | acid | Radical | Crosslinking | | |
| | | Resist | compound | compound | scavenger | agent | Solvent 1 | Solvent 2 |
| | | composition | (pbw) | (pbw) | (pbw) | (pbw) | (pbw) | (pbw) |
| Example | 1-1 | R-01 | I-1 (11.5) | CA-1 (12.8) | — | — | PGMEA (900) | AcOH (100) |
| | 1-2 | R-02 | I-1 (11.5) | CA-2 (4.2) | — | — | PGMEA (900) | AcOH (100) |
| | 1-3 | R-03 | I-1 (11.5) | CA-3 (4.1) | — | — | PGMEA (900) | AcOH (100) |
| | 1-4 | R-04 | I-1 (11.5) | CA-4 (5.2) | — | — | PGMEA (900) | AcOH (100) |
| | 1-5 | R-05 | I-1 (11.5) | CA-5 (5.9) | — | — | PGMEA (900) | AcOH (100) |
| | 1-6 | R-06 | I-1 (11.5) | CA-6 (8.5) | — | — | PGMEA (900) | AcOH (100) |
| | 1-7 | R-07 | I-1 (11.5) | CA-7 (8.6) | — | — | PGMEA (900) | AcOH (100) |
| | 1-8 | R-08 | I-1 (11.5) | CA-8 (4.1) | — | — | PGMEA (900) | AcOH (100) |
| | 1-9 | R-09 | I-1 (11.5) | CA-9 (5.1) | — | — | PGMEA (900) | AcOH (100) |
| | 1-10 | R-10 | I-1 (11.5) | CA-10 (5.3) | — | — | PGMEA (900) | AcOH (100) |
| | 1-11 | R-11 | I-2 (15.4) | CA-4 (5.2) | — | — | PGMEA (900) | AcOH (100) |
| | 1-12 | R-12 | I-3 (13.0) | CA-5 (5.9) | — | — | PGMEA (900) | GBL (100) |
| | 1-13 | R-13 | I-1 (17.5) | CA-4 (5.2) | — | — | PGMEA (900) | AcOH (100) |
| | 1-14 | R-14 | I-1 (11.5) | CA-4 (7.7) | — | — | PGMEA (900) | AcOH (100) |
| | 1-15 | R-15 | I-1 (5.8) | CA-5 (5.9) | — | — | PGMEA (900) | AcOH (100) |
| | | | I-3 (6.5) | | | | | |
| | 1-16 | R-16 | I-1 (11.5) | CA-1 (12.8) | — | — | HBM (900) | AcOH (100) |
| | 1-17 | R-17 | I-1 (11.5) | CA-1 (12.8) | — | — | PGMEA (900) | PA (100) |
| | 1-18 | R-18 | I-1 (11.5) | CA-1 (12.8) | T-1 (1) | — | PGMEA (900) | AcOH (100) |
| | 1-19 | R-19 | I-1 (11.5) | CA-1 (12.8) | — | L-1 (1) | PGMEA (900) | AcOH (100) |

TABLE 2

| | | | | Photoacid | Sensitivity | | |
|---|---|---|---|---|---|---|---|
| | | Resist | Base polymer | generator | modifier | Solvent 1 | Solvent 2 |
| | | composition | (pbw) | (pbw) | (pbw) | (pbw) | (pbw) |
| Comparative | 1-1 | CR-01 | P-1 (80) | PAG-1 (19.0) | Q-1 (6.2) | PGMEA (1890) | GBL (210) |
| Example | 1-2 | CR-02 | P-1 (80) | PAG-2 (21.0) | Q-1 (6.2) | PGMEA (1890) | GBL (210) |
| | 1-3 | CR-03 | P-1 (80) | PAG-1 (19.0) | Q-2 (8.7) | PGMEA (1890) | GBL (210) |

In Table 1, the hypervalent iodine compounds (I-1 to 1-3), the carboxylic acid compounds (CA-1 to CA-10), the radical scavenger T-1, the crosslinking agent L-1, and the solvent are as follows.

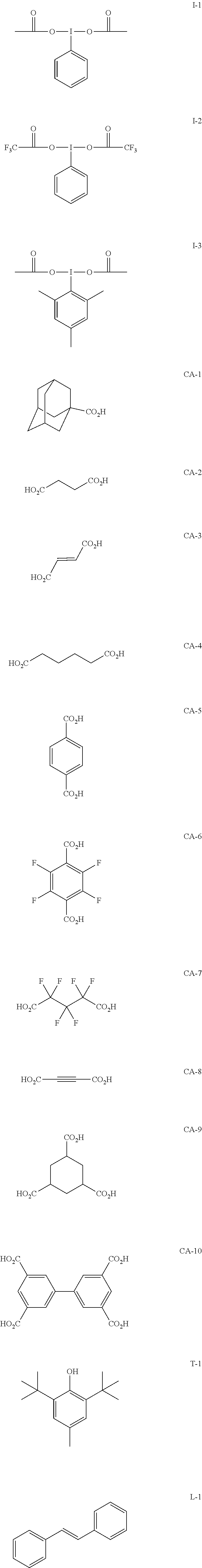

### Solvent:

PGMEA (propylene glycol monomethyl ether acetate)
AcOH (acetic acid)
HBM (methyl 2-hydroxyisobutyrate)
PA (propionic acid)
GBL (γ-butyrolactone)

In Table 2, the base polymer (P-1), the photoacid generator (PAG-1, PAG-2), and the sensitivity modifier (Q-1, Q-2) are as follows.

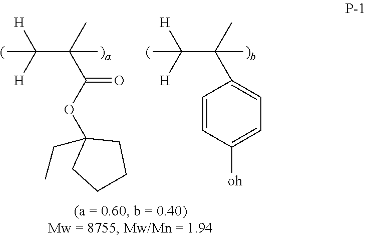

Mw=8755 (in terms of polystyrene), Mw/Mn=1.94

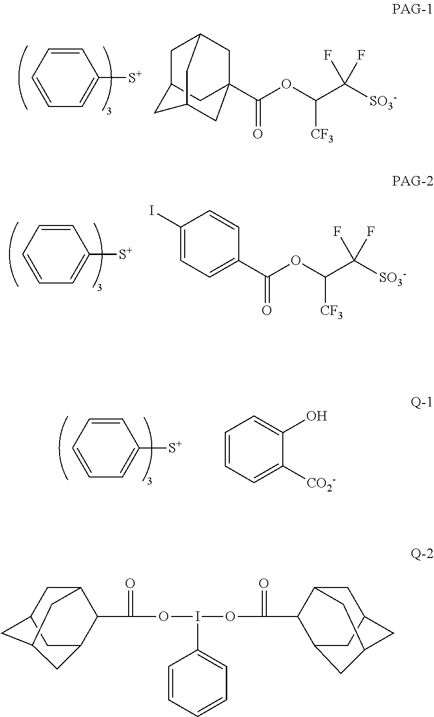

### [2] Evaluation of EUV Lithography (Line-and-Space Pattern)

### Examples 2-1 to 2-19, Comparative Examples 2-1 to 2-3

Each of the resist compositions (R-01 to R-19, CR-01 to CR-03) was spin-coated on a Si substrate having a 20-nm coating of silicon-containing spin-on hard mask SHB-A940 (silicon content: 43 wt %) manufactured by Shin-Etsu Chemical Co., Ltd., and prebaked (PAB) on a hotplate at the temperature shown in Table 3 for 60 seconds to form a resist film of 40 nm thick. The resist film was exposed to a pattern of 36 nm line-and-space (LS) 1:1 using EUV scanner NXE3400 (NA 0.33, σ0.9, 90 degree dipole illumination) manufactured by ASML, subjected to PEB on a hot plate at the temperature shown in Table 3 for 60 seconds, and developed in a developer shown in Table 3 for 30 seconds to form a negative LS pattern having a space width of 18 nm and a pitch of 36 nm.

The obtained resist pattern was evaluated as follows. The results are shown in Table 3.

### [Evaluation of Sensitivity]

The LS pattern was observed using a length measurement SEM (CG-6300) manufactured by Hitachi High-Tech Corporation, and the optimum exposure dose (Eop, mJ/cm²) which provided an LS pattern with a space width of 18 nm and a pitch of 36 nm was determined and reported as sensitivity.

### [Evaluation of LWR]

From the LS pattern obtained by irradiation with the optimum exposure dose (Eop), the space width was measured under the length measurement SEM (CG-6300) manufactured by Hitachi High-Tech Corporation) at longitudinally spaced apart 10 points, from which a 3-fold value (3a) of the standard deviation (a) was determined as LWR (nm). A smaller value indicates a pattern having a lower roughness and more uniform space width.

### [Evaluation of Maximum Resolution]

The maximum line width (nm) to be resolved at the time of forming the LS pattern while increasing the exposure dose little by little from the optimum exposure dose (Eop), was determined under length measurement SEM (CG-6300) manufactured by Hitachi High-Tech Corporation, and reported as maximum resolution (nm). A smaller value indicates a pattern having a better maximum resolution and smaller size pattern.

TABLE 3

| | | | | | | | Maximum |
|---|---|---|---|---|---|---|---|
| | | Resist | PAB/PEB | | EoP | LWR | resolution |
| | | composition | (° C.) | Developer | (mJ/cm²) | (nm) | (nm) |
| Example | 2-1 | R-01 | 130/60 | TMAH | 38 | 3.6 | 15 |
| | 2-2 | R-02 | 130/60 | TMAH | 50 | 2.7 | 15 |
| | 2-3 | R-03 | 130/60 | TMAH | 49 | 2.9 | 15 |
| | 2-4 | R-04 | 130/60 | TMAH | 43 | 3.2 | 13 |
| | 2-5 | R-05 | 130/60 | TMAH | 45 | 3.4 | 14 |
| | 2-6 | R-06 | 130/60 | TMAH | 44 | 2.9 | 12 |
| | 2-7 | R-07 | 130/60 | TMAH | 50 | 2.6 | 15 |
| | 2-8 | R-08 | 130/60 | TMAH | 45 | 3.0 | 12 |
| | 2-9 | R-09 | 130/60 | TMAH | 47 | 3.3 | 14 |
| | 2-10 | R-10 | 130/60 | TMAH | 49 | 3.5 | 14 |
| | 2-11 | R-11 | 130/60 | TMAH | 43 | 3.2 | 13 |
| | 2-12 | R-12 | 130/60 | TMAH | 43 | 3.3 | 13 |
| | 2-13 | R-13 | 130/60 | TMAH | 46 | 3.3 | 14 |
| | 2-14 | R-14 | 130/60 | TMAH | 41 | 3.2 | 14 |
| | 2-15 | R-15 | 130/60 | TMAH | 44 | 3.3 | 13 |
| | 2-16 | R-16 | 130/60 | TMAH | 37 | 3.0 | 12 |
| | 2-17 | R-17 | 130/60 | TMAH | 37 | 2.8 | 12 |
| | 2-18 | R-18 | 130/60 | TMAH | 40 | 2.3 | 10 |
| | 2-19 | R-19 | 130/60 | TMAH | 36 | 2.3 | 10 |
| Comparative | 2-1 | CR-01 | 105/90 | nBA | 65 | 4.0 | 17 |
| Example | 2-2 | CR-02 | 105/90 | nBA | 63 | 3.9 | 17 |
| | 2-3 | CR-03 | 105/90 | nBA | 68 | 3.7 | 17 |

Developer: nBA (butyl acetate)
TMAH (2.38 mass % aqueous tetramethylammonium hydroxide solution)

From the results shown in Table 3, it is evident that according to the negative resist pattern forming process of the present invention, a negative resist pattern excellent in sensitivity, LWR, and resolution can be formed in LS pattern formation by EUV exposure.

### [3] Evaluation of EUV Lithography (Pillar Pattern)

### Examples 3-1 to 3-19 and Comparative Examples 3-1 to 3-3

Each of the resist compositions (R-01 to R-19, CR-01 to CR-03) was spin-coated on a Si substrate having a 20-nm coating of silicon-containing spin-on hard mask SHB-A940 (silicon content: 43 wt %) manufactured by Shin-Etsu Chemical Co., Ltd., and subjected to PAB on a hotplate at the temperature shown in Table 4 for 60 seconds to form a resist film of 50 nm thick. Next, the resist film was exposed using an EUV scanner NXE3400 (NA 0.33, a 0.9/0.6, quadrupole illumination, mask of pillar pattern with on-wafer dimensions of pitch 64 nm and +20% bias) manufactured by ASML, subjected to PEB on a hot plate at a temperature shown in Table 4 for 60 seconds, and developed in a developer shown in Table 4 for 30 seconds to form a pillar pattern having a size of 32 nm.

The obtained resist pattern was evaluated as follows. The results are shown in Table 4.

### [Evaluation of Sensitivity]

The pillar pattern was observed using a length measurement SEM (CG-6300) manufactured by Hitachi High-Tech Corporation, and the optimum exposure dose (Eop, mJ/cm²) which provided a pillar pattern having a size of 22 nm was determined and reported as sensitivity.

### [Evaluation of CDU]

The size of 50 pillar patterns obtained by irradiation with the optimum exposure dose was measured, from which a 3-fold value (3a) of the standard deviation (a) was computed and reported as CDU (nm). A smaller value of CDU indicates a hole pattern with more uniform pillar diameter.

### [Evaluation of Maximum Resolution]

The maximum pillar diameter (nm) to be resolved at the time of forming the pillar pattern while decreasing the exposure dose little by little from the optimum exposure dose (Eop), was determined under length measurement SEM (CG-6300) manufactured by Hitachi High-Tech Corporation, and reported as maximum resolution (nm). A smaller value indicates a pattern having a better maximum resolution and smaller pillar diameter.

TABLE 4

| | | | | | | | Maximum |
|---|---|---|---|---|---|---|---|
| | | Resist | PAB/PEB | | EoP | CDU | resolution |
| | | composition | (° C.) | Developer | (mJ/cm²) | (nm) | (nm) |
| Example | 3-1 | R-01 | 130/60 | TMAH | 25 | 2.9 | 29 |
| | 3-2 | R-02 | 130/60 | TMAH | 27 | 2.9 | 27 |
| | 3-3 | R-03 | 130/60 | TMAH | 27 | 2.9 | 27 |
| | 3-4 | R-04 | 130/60 | TMAH | 29 | 2.7 | 27 |
| | 3-5 | R-05 | 130/60 | TMAH | 29 | 2.8 | 27 |
| | 3-6 | R-06 | 130/60 | TMAH | 27 | 2.5 | 25 |
| | 3-7 | R-07 | 130/60 | TMAH | 26 | 2.9 | 27 |
| | 3-8 | R-08 | 130/60 | TMAH | 28 | 2.6 | 25 |
| | 3-9 | R-09 | 130/60 | TMAH | 29 | 2.9 | 29 |
| | 3-10 | R-10 | 130/60 | TMAH | 29 | 2.8 | 29 |
| | 3-11 | R-11 | 130/60 | TMAH | 29 | 2.7 | 27 |
| | 3-12 | R-12 | 130/60 | TMAH | 28 | 2.6 | 25 |
| | 3-13 | R-13 | 130/60 | TMAH | 29 | 2.9 | 29 |
| | 3-14 | R-14 | 130/60 | TMAH | 28 | 2.8 | 29 |
| | 3-15 | R-15 | 130/60 | TMAH | 28 | 2.7 | 27 |
| | 3-16 | R-16 | 130/60 | TMAH | 24 | 2.5 | 26 |
| | 3-17 | R-17 | 130/60 | TMAH | 24 | 2.6 | 27 |
| | 3-18 | R-18 | 130/60 | TMAH | 27 | 2.2 | 22 |
| | 3-19 | R-19 | 130/60 | TMAH | 23 | 2.2 | 22 |
| Comparative | 3-1 | CR-01 | 105/90 | nBA | 33 | 3.5 | 33 |
| Example | 3-2 | CR-02 | 105/90 | nBA | 31 | 3.4 | 31 |
| | 3-3 | CR-03 | 105/90 | nBA | 35 | 3.3 | 31 |

From the results shown in Table 4, it is evident that according to the negative resist pattern forming process of the present invention, a negative resist pattern excellent in sensitivity, CDU, and resolution can be formed in pillar pattern formation by EUV exposure.

Japanese Patent Application No. 2024-035809 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A negative resist pattern forming process, comprising:
(i) forming a resist film on a substrate using a resist composition containing a hypervalent iodine compound, a carboxylic acid compound, and a solvent;
(ii) exposing the resist film with a high-energy radiation; and
(iii) developing the exposed resist film using a developer that dissolves an unexposed portion and does not dissolve an exposed portion.

2. The negative resist pattern forming process according to claim 1, wherein the developer is an alkaline developer.

3. The negative resist pattern forming process according to claim 1, wherein the high-energy radiation is an electron beam or an extreme ultraviolet ray.

4. The negative resist pattern forming process according to claim 1, wherein the hypervalent iodine compound has the following formula (1): 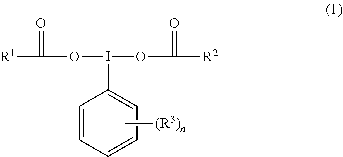
wherein n is an integer of 0 to 5,
R¹ and R² are each independently halogen or a C₁-C₁₀ hydrocarbyl group which may contain a heteroatom, R¹ and R² may bond together to form a ring with the carbon atoms to which they are attached and intervenient atoms, and
R³ is halogen or a C₁-C₄₀ hydrocarbyl group which may contain a heteroatom, and when n is an integer of 2 to 5, a plurality of R³ may be the same or different.

5. The negative resist pattern forming process according to claim 1, wherein the carboxylic acid compound has the following formula (2): 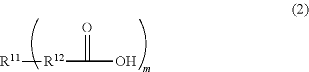
wherein m is an integer of 1 to 4,
R¹¹ is a C₁-C₄₀ m-valent hydrocarbon group or C₂-C₄₀ m-valent heterocyclic group, when m is 2, R¹¹ may be an ether bond, carbonyl group, azo group, thioether bond, carbonate bond, carbamate bond, sulfinyl group or sulfonyl group, some or all of the hydrogen atoms in the m-valent hydrocarbon group or m-valent heterocyclic group may be substituted by a heteroatom-containing moiety, and some constituent —CH₂— in the m-valent hydrocarbon group may be substituted by a heteroatom-containing moiety,
R¹² is a single bond or a C₁-C₁₀ hydrocarbylene group, some or all of the hydrogen atoms in the hydrocarbylene group may be substituted by a heteroatom-containing moiety, and some constituent —CH₂— in the hydrocarbylene group may be substituted by a heteroatom-containing moiety, and when m is an integer of 2 to 4, a plurality of R¹² may be the same or different.

6. The negative resist pattern forming process according to claim 5, wherein m is an integer of 2 to 4.

7. The negative resist pattern forming process according to claim 1, wherein the resist composition further contains a crosslinking agent.

8. The negative resist pattern forming process according to claim 1, wherein the resist composition further contains a radical scavenger.
